(19) United States
(12) Patent Application Publication
(10) Pub. No.: US 2025/0275419 A1
(43) Pub. Date: Aug. 28, 2025

(54) DISPLAY DEVICE

(71) Applicant: LG Display Co., Ltd., Seoul (KR)

(72) Inventors: Hyoung-Su KIM, Paju-si (KR); Hyesook KIM, Paju-si (KR); Hyunsuk LEE, Paju-si (KR)

(21) Appl. No.: 18/913,479

(22) Filed: Oct. 11, 2024

(30) Foreign Application Priority Data
Feb. 23, 2024 (KR) 10-2024-0026312

(51) Int. Cl. H10K 59/80; H10K 59/122

(52) U.S. Cl. CPC H10K 59/8723; H10K 59/873; H10K 59/122

(57) ABSTRACT

A display device includes a base substrate including an active area and a non-active area surrounding the active area and a support member disposed in the non-active area over the base substrate. The support member includes two or more layers. The display device has a narrow bezel.

### CROSS REFERENCE TO RELATED APPLICATION

This application claims priority from Korean Patent Application No. 10-2024-0026312, filed on Feb. 23, 2024, which is hereby incorporated by reference for all purposes as if fully set forth herein.

### BACKGROUND

### Technical Field

Embodiments relate to a display device provided with a support member supporting a deposition mask on a non-active area to realize a narrow bezel.

### Description of the Related Art

Since the dawn of the information age, the display field that visually expresses electrical information signals has developed rapidly, and various display devices having excellent characteristics such as a thin profile, while being light weight, and having low power consumption have been responsively developed.

Specific examples of such display devices include liquid crystal display devices (LCDs), plasma panel display devices (PDPs), field emission display devices (FEDs), organic light-emitting display devices, and the like.

Recently, there has been active research into providing larger active areas on display devices. Specifically, narrow bezel technology is being explored to provide users with a wider and larger image by minimizing edge areas in which no images are displayed while increasing an area where images are displayed.

### BRIEF SUMMARY

In general, a display device may be provided with a passivation layer (or protection layer) to cover a light-emitting element to protect the same from external moisture and/or oxygen. The passivation layer may be configured to extend from an active area of the display device to a non-active area to cover the top and side portions of the light-emitting element.

In this case, as the width of the passivation layer in the non-active area increases, the bezel area also increases. Therefore, to achieve a narrow bezel, the width of the passivation layer in the non-active area must be minimized.

A deposition mask is required to form a passivation layer, and as the display panel has recently become larger, the size of the deposition mask has also increased, thereby causing the deposition mask to sag downward. To overcome or reduce this problem of sagging of the deposition mask, the display device may be provided with a support member for supporting the deposition mask.

Since the position of the deposition mask is determined by the position of the support member, where the support member is located is important. For example, when the support member is located higher than necessary from a base substrate, the gap between the deposition mask and the light-emitting element seated on the support member may also increase. Such an increased gap between the light-emitting element and the deposition mask may increase the width of the passivation layer provided in the non-active area, thereby making it difficult to realize a narrow bezel.

Accordingly, the inventors of the present disclosure have invented a display device in which a narrow bezel may be realized by forming a passivation layer deposited in the non-active area with a width of 2.0 mm or less by minimizing the height difference between the support member disposed in the non-active area over the base substrate and the light-emitting element.

According to embodiments, a support member may be formed without the addition of a mask sheet, as the support member including two or more layers is formed of the same material as the overcoat layer and the bank layer located under the light-emitting element. Accordingly, it is possible to provide a display device having a structure capable of reducing processing time and cost for manufacturing the support member.

Embodiments may provide a display device including a base substrate including an active area and a non-active area surrounding the active area; and a support member disposed in the non-active area over the base substrate, wherein the support member includes two or more layers.

According to embodiments, by minimizing the height difference between the support member disposed in the non-active area of the base substrate and the light-emitting element, the passivation layer deposited in the non-active area may be formed to have a width of 2.0 mm or less, thereby providing a display device able to realize a narrow bezel structure.

According to embodiments, the support member including two or more layers may be formed of the same material as the overcoat layer and the bank layer located under the light-emitting element. Accordingly, since the support member may be formed without the addition of a mask sheet, processing time and cost for manufacturing the support member may be reduced, and a display device enabling process optimization may be provided.

### DESCRIPTION OF THE SEVERAL VIEWS OF THE DRAWINGS

The above and other objectives, features, and advantages of the present disclosure will be more clearly understood from the following detailed description, taken in conjunction with the accompanying drawings, in which:

FIG. 1 illustrates a system configuration of a display device according to an embodiment of the present disclosure;

FIG. 2 is a cross-sectional view of the display device, shown in FIG. 1 taken along line A-A′;

FIG. 3 illustrates a position in which a deposition mask is seated on a support member according to embodiments;

FIG. 4 is a perspective view illustrating a deposition mask for fabricating a plurality of display panels;

FIG. 5 is a cross-sectional view illustrating a comparative example in which a support member supporting a mask stick is disposed in a non-active area;

FIGS. 6A and 6B schematically illustrate changes in the width of a passivation film provided in a non-active area according to the height of a mask stick;

FIG. 7 is a graph illustrating the size of a shadow area according to the distance between a mask stick and a light-emitting element;

FIG. 8 is a cross-sectional view illustrating a display device according to another embodiment of the present disclosure;

FIG. 9 is a plan view illustrating a display device according to an embodiment of the present disclosure; and

FIGS. 10 and 11 are plan views each illustrating a display device according to according to another embodiment of the present disclosure.

### DETAILED DESCRIPTION

In the following description of examples or an embodiment of the present disclosure of the present disclosure, reference will be made to the accompanying drawings in which it is shown by way of illustration specific examples or an embodiment of the present disclosure that can be implemented, and in which the same reference numerals and signs can be used to designate the same or like components even when they are shown in different accompanying drawings from one another. Further, in the following description of examples or an embodiment of the present disclosure of the present disclosure, detailed descriptions of well-known functions and components incorporated herein will be omitted when it is determined that the description may make the subject matter in some an embodiment of the present disclosure of the present disclosure rather unclear. The terms such as “including,” “having,” “containing,” “constituting” “made up of,” and “formed of” used herein are generally intended to allow other components to be added unless the terms are used with the term “only.” As used herein, singular forms are intended to include plural forms unless the context clearly indicates otherwise.

Terms, such as “first,” “second,” “A,” “B,” “(A),” or “(B)” may be used herein to describe elements of the present disclosure. Each of these terms is not used to define essence, order, sequence, or number of elements, etc., but is used merely to distinguish the corresponding element from other elements.

When it is mentioned that a first element “is connected or coupled to,” “contacts or overlaps,” etc., a second element, it should be interpreted that, not only can the first element “be directly connected or coupled to” or “directly contact or overlap” the second element, but a third element can also be “interposed” between the first and second elements, or the first and second elements can “be connected or coupled to,” “contact or overlap,” etc., each other via a fourth element. Here, the second element may be included in at least one of two or more elements that “are connected or coupled to,” “contact or overlap,” etc., each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes, etc., are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompass all the meanings of the term “can.”

Hereinafter, a variety of an embodiment of the present disclosure will be described in detail with reference to the accompanying drawings.

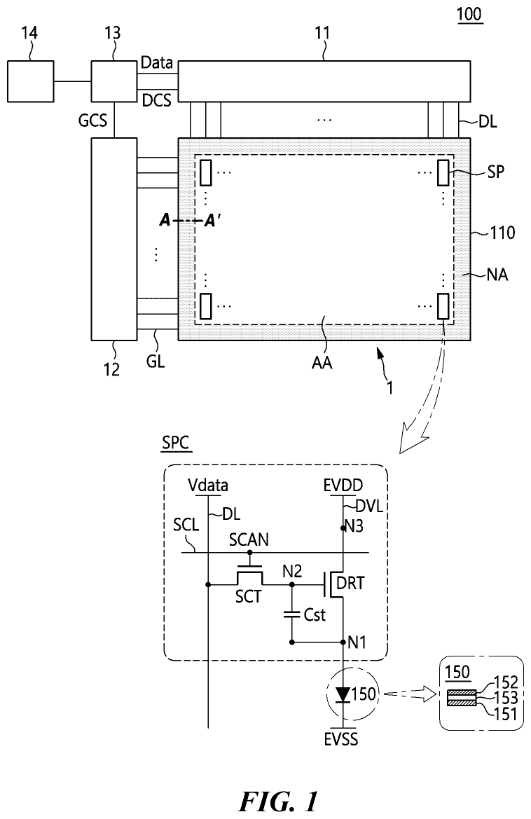

FIG. 1 illustrates a system configuration of a display device according to an embodiment of the present disclosure.

Referring to FIG. 1, a display driver system of a display device 100 according to embodiments of the present disclosure may include a display panel 1 and a display driver circuit for driving the display panel 1.

The display panel 1 may include an active area AA where images are displayed and a non-active area NA where no images are displayed. The display panel 1 may include a plurality of subpixels SP disposed on a base substrate 110 to display images.

The display panel 1 may include a plurality of signal lines disposed on the base substrate 110. For example, the signal lines may include data lines DL, gate lines GL, driving voltage lines, and the like.

Each of the data lines DL may be arranged to extend in a first direction (e.g., column or row direction), and each of the gate lines GL may be arranged to extend in a direction intersecting the first direction.

The display driver circuit may include a data driver circuit 11, a gate driver circuit 12, and the like, and may further include a controller 13 to control the data driver circuit 11 and the gate driver circuit 12.

The data driver circuit 11 may output data signals (also known as data voltages) corresponding to video signals to the data lines DL. The gate driver circuit 12 may generate gate signals and output the gate signals to the gate lines GL. The controller 13 may convert video data input from an external host 14 in accordance with a data signal format used in the data driver circuit 11 and supply the converted video data to the data driver circuit 11.

The data driver circuit 11 may include one or more source driver integrated circuits. For example, each of the source driver integrated circuits may be connected to the display panel 1 by a tape-automated bonding (TAB) method, connected to a bonding pad on the display panel 1 by a chip-on-glass (COG) method or a chip-on-panel (COP) method, or implemented by a chip-on-film (COF) method to be connected to the display panel 1.

The gate driver circuit 12 may be connected to the display panel 1 by a TAB method, or may be connected to a bonding pad of the display panel 1 by a COG or COP method, may be connected to the display panel 1 by a COF method, or may be provided in the non-active area NA of the display panel 1 by a Gat-In-panel (GIP) method.

Referring to FIG. 1, in the display device 100 according to embodiments of the present disclosure, each of the subpixels SP may include a light-emitting element 150 and a pixel driver circuit SPC for driving the light-emitting element 150. The pixel driver circuit SPC may include a driving transistor DRT, a scanning transistor SCT, and a storage capacitor Cst.

The driving transistor DRT may drive the light-emitting element 150 by controlling a current flowing to the light-emitting element 150. The scanning transistor SCT may transfer a data voltage Vdata to the second node N2, which is a gate node of the driving transistor DRT. The storage capacitor Cst may be configured to maintain the voltage for a period of time.

The light-emitting element 150 may include an anode 151 and a cathode 152, and a light-emitting layer 153 located between the anode 151 and the cathode 152. The anode 151 may be a pixel electrode in the formation of the light-emitting element 150 of each of the subpixels SP, and may be electrically connected to the first node N1 of the driving transistor DRT. The cathode 152 may be a common electrode involved in the formation of the light-emitting element 150 of all of the subpixels SP, and an applied base voltage EVSS may be applied to the cathode 152.

For example, the light-emitting element 150 may be an organic light-emitting diode (OLED), an inorganic material-based light-emitting diode (LED), a quantum dot light-emitting element, which is a semiconductor crystal that emits light by itself, or the like.

The driving transistor DRT may be a transistor for driving the light-emitting element 150, which may include a first node N1, a second node N2, and a third node N3. The first node N1 may be a source node or a drain node, and may be electrically connected to the anode 151 of the light-emitting element 150. The second node N2 may be a gate node, and may be electrically connected to the source or drain node of the scanning transistor SCT. The third node N3 may be the drain or source node, and may be electrically connected to a driving voltage line DVL through which a driving voltage EVDD is supplied. In the following, for the sake of brevity, a case in which the first node N1 is the source node and the third node N3 is the drain node will be described as an example.

The scanning transistor SCT may switch the connection between the data line DL and the second node N2 of the driving transistor DRT. The scanning transistor SCT may control the connection between the second node N2 of the driving transistor DRT and the corresponding data line DL among the data lines DL in response to a scanning signal SCAN supplied from a scan line SCL, which is a type of gate line GL.

The storage capacitor Cst may be configured between the first node N1 and the second node N2 of the driving transistor DRT.

The structure of each of the subpixels SP shown in FIG. 1 is for illustrative purposes only, and may further include one or more transistors or one or more capacitors. In another example, the entirety of the subpixels may have the same structure, or some of the subpixels may have different structures. Each of the driving transistor DRT and the scanning transistor SCT may be an n-type transistor or a p-type transistor.

The display device 100 according to embodiments may also have a top emission structure or a bottom emission structure. Hereinafter, the display device according to the embodiments will be described as having a bottom emission structure.

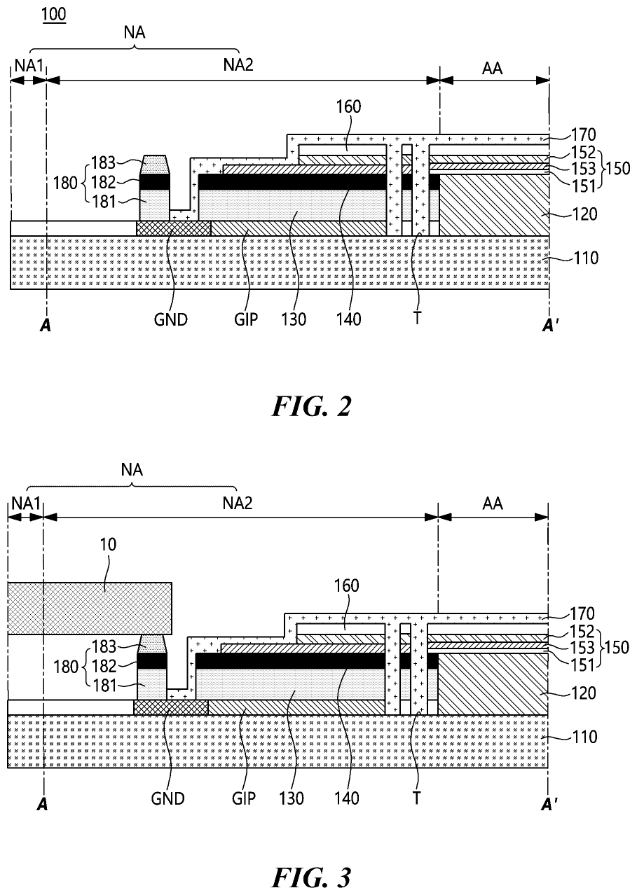

FIG. 2 is a cross-sectional view of the display device shown in FIG. 1 taken along line A-A′, and FIG. 3 illustrates a position in which a deposition mask is seated on a support member according to an embodiment of the present disclosure.

Referring to FIGS. 2 and 3, the display device 100 may include a base substrate 110, a subpixel portion 120, an overcoat layer 130, a bank layer 140, a light-emitting element 150, a capping layer 160, a passivation layer (or protection layer) 170, and a support member 180.

The base substrate 110 is for supporting various components of the display device 100, and may include an active area AA for displaying images by a plurality of subpixels SP and a non-active area NA surrounding the active area AA. For example, the base substrate 110 may be formed of an insulating material, such as a glass substrate or a plastic substrate.

In the present embodiment, the base substrate 110 may include a Thin Film Transistor (TFT) provided thereon, a GIP circuit, a ground line GND, and the like.

The subpixel portion 120 may be disposed in the active area AA over the base substrate 110. For example, the subpixel portion 120 may include an anode 151, transistors DRT and SCT, and a storage capacitor Cst.

The overcoat layer 130 may be disposed in the non-active area NA to protect devices or patterns located thereunder and to reduce the height difference of a structure caused by the devices or patterns located thereunder. For example, the overcoat layer 130 may be formed of an organic material such as an acrylic resin, an epoxy resin, a phenolic resin, polyamide resin, a polyimide resin, or the like. However, the material of the overcoat layer 130 is not limited thereto, and the overcoat layer 130 may be formed of at least one inorganic material and/or at least one organic material.

The bank layer 140 may be disposed over the overcoat layer 130. The bank layer 140 is shown as being only formed in non-active area NA, but the bank layer 140 may be provided in both the active area AA and the non-active area NA. For example, the bank layer 140 may be provided with openings allowing light to be output from single pixels. That is, the bank layer 140 is provided in the active area AA and the non-active area NA, and the bank layer 140 provided in the active area AA has the openings allowing the anodes 151 of the respective pixels to be exposed therethrough and light to be output therethrough.

The bank layer 140 may be formed as@ at least one inorganic film or at least one organic film. In another example, the bank layer 140 may be provided by laminating the at least one inorganic film with the at least one organic film.

The light-emitting element 150 may be disposed over the subpixel portion 120 and the bank layer 140. For example, the light-emitting element 150 may be disposed in the active area AA and the non-active area NA, and may include the anode 151, the cathode 152, and the light-emitting layer 153 disposed between the anode 151 and the cathode 152.

The light-emitting layer 153 may include a hole transporting layer, an organic light-emitting layer, and an electron transporting layer. In this case, when a voltage is applied to the anode 151 and the cathode 152, holes and electrons are transported through the hole transport layer and the electron transport layer, respectively, to the organic light-emitting layer, where the holes and electrons combine with each other to emit light. Since the area including the light-emitting element 150 is provided with pixels, the area in which the light-emitting element 150 is formed may be defined as the active area AA. The area surrounding the active area AA may be defined as the non-active area NA.

The capping layer 160 may be disposed over the light-emitting element 150. For example, the capping layer 160 may be provided in the active area AA and the non-active area NA, and may cover the top portion of the cathode 152 to minimize the penetration of oxygen and/or moisture into the cathode 152.

The passivation layer 170 may be provided in the active area AA and the non-active area NA, and may protect the light-emitting element 150 located thereunder from external moisture, oxygen, shock, and the like. For example, the passivation layer 170 may be configured to cover the top portion of the capping layer 160 and side portions of the capping layer 160, the light-emitting element 150, the bank layer 140, and the overcoat layer 130.

An edge of the passivation layer 170 may be provided to extend outward from the side portion of the overcoat layer 130 to further cover a portion of the base substrate 110. For example, the passivation layer 170 may be provided to extend from the active area AA to the non-active area NA such that the extended edge does not extend beyond the support member 180. Accordingly, the edge of the passivation layer 170 may be disposed between the overcoat layer 130 and the support member 180 over the non-active area NA.

The support member 180 may be disposed in the non-active area NA over the base substrate 110 and may include two or more layers. For example, the support member 180 may be disposed to contact the edge of the passivation layer 170 in the non-active area NA and may be configured to have a height of 0.003 mm to 0.005 mm.

The support member 180 may be used to support the deposition mask 10 used in the deposition process for forming a film such as the passivation layer 170 over the base substrate 110. In other words, the display panel 1 may be formed by cutting a single base substrate 20 at a desired size, wherein the support member 180 may be provided in the non-active area NA to support the deposition mask 10 for forming the passivation layer 170 over the base substrate 20.

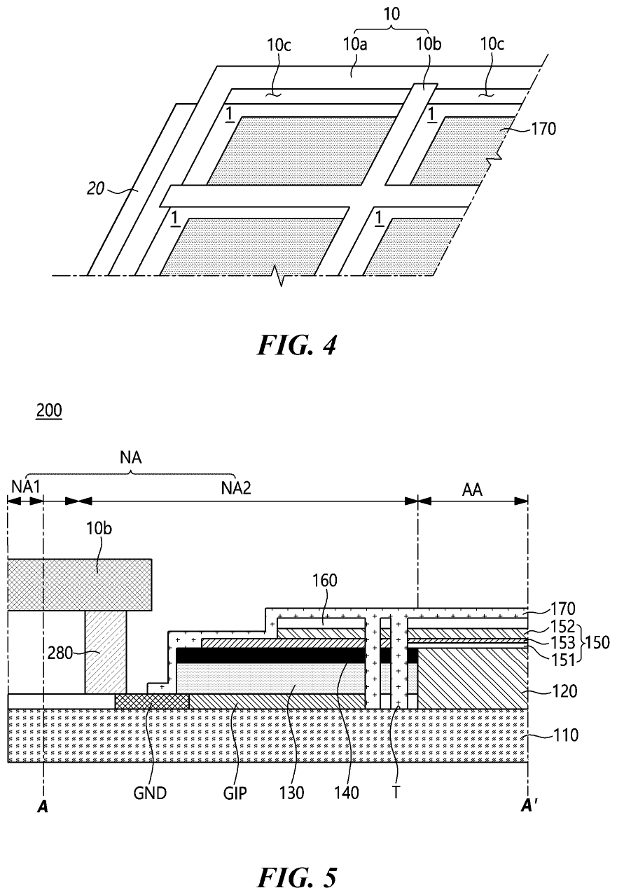

FIG. 4 is a perspective view illustrating a deposition mask for fabricating a plurality of display panels. With reference to FIG. 4, a deposition mask 10 seated on the support member 180 will be described as follows.

Referring to FIG. 4, the deposition mask 10 may be used to deposit a passivation layer 170 over the base substrate 110. For example, the deposition mask 10 may include a mask frame 10a positioned over the periphery of the base substrate 20 and a plurality of mask sticks 10b dividing the mask frame 10a. The mask frame 10a and the mask sticks 10b form a plurality of open areas 10c in the deposition mask 10, and an inorganic material for forming the passivation layer 170 may be deposited on the base substrate 20 through the open areas 10c.

Accordingly, in the deposition process, an inorganic material is deposited on portions corresponding to the open areas 10c of the deposition mask 10, and is not deposited on portions corresponding to the mask frame 10a and the mask sticks 10b. When the entire process for forming the display panel 1, including the deposition of the inorganic material, are completed, a plurality of display panels 1 formed on the base substrate 20 may be separated into individual display panels 1. In this case, the respective display panels 1 may be separated from each other by a scribing process using a laser or the like.

As the size of the display panel 1 increases, the size of the mask sticks 10b also increases, and there is a problem of sagging downward. To solve this sagging problem of the mask sticks 10b, support members 180 for supporting the mask sticks 10b may be disposed in the non-active area NA.

The width of the passivation layer 170 formed in the non-active area NA may vary depending on the position of the support member 180 supporting the mask sticks 10b. Here, the width of the passivation layer 170 disposed in the non-active area NA may be referred to as a “shadow area S,” and the width of the shadow area S may be 1.9 mm to 2.0 mm according to the present embodiment.

As the width of the shadow area S increases in the display device 100, the width of the bezel also increases. Therefore, the position of the support member 180 is one of the most important factors in forming a narrow bezel.

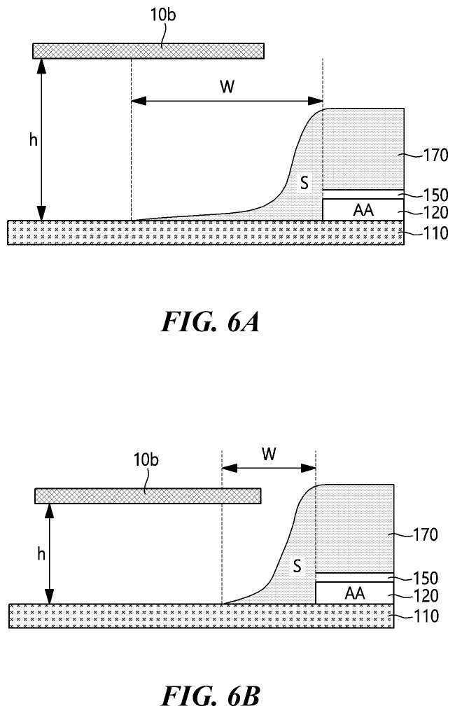

FIG. 5 is a cross-sectional view illustrating a comparative example in which a support member supporting a mask stick is disposed in a non-active area, and FIGS. 6A and 6B schematically illustrate changes in the width of a passivation film provided in a non-active area according to the height of a mask stick.

With reference to FIGS. 5 to 6B, changes in the width of the shadow area S with the height of a mask stick 10b are described as follows.

A support member 280 of a display device 200 of the comparative example may be disposed in a non-active area NA to support a of the bottom of the mask stick 10b. In this case, the width of a passivation layer 170 formed in the non-active area NA may vary depending on the height at which the mask stick 10b is located.

In other words, as shown in FIGS. 6A and 6B, as the distance h between the mask stick 10b and a light-emitting element 150 increases, the width w of the passivation layer 170 formed in the non-active area NA may be increased. This is because when an inorganic material is deposited through the open areas 10c between the mask sticks 10b, the greater the distance h between the light-emitting element 150 and the mask stick 10b, the more the inorganic material migrates toward the non-active area NA when deposited. Therefore, it is important to appropriately adjust the distance between the light-emitting element 150 and the mask sticks 10b.

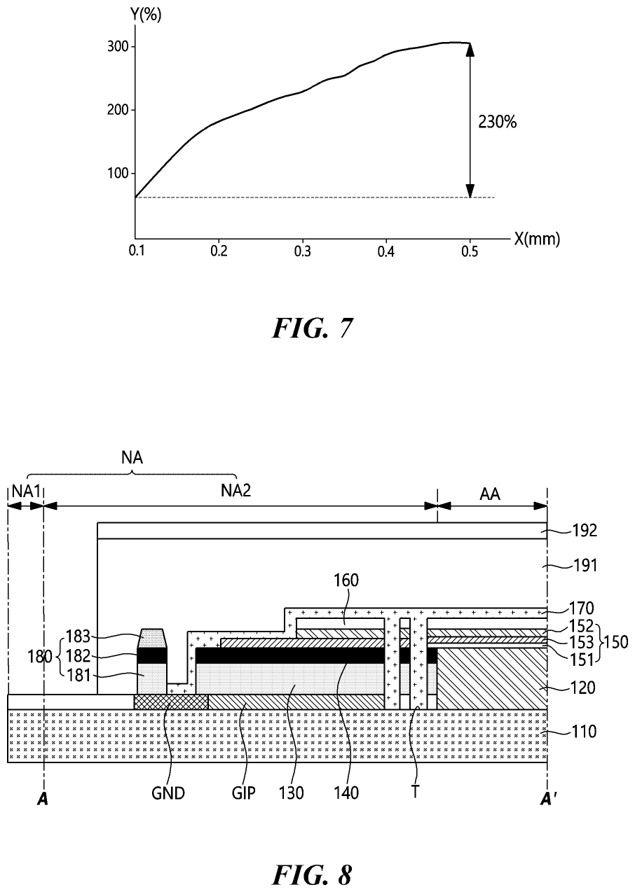

FIG. 7 is a graph illustrating the rate of increase of the width of a shadow area according to the distance between a mask stick and a light-emitting element. In FIG. 7, the X-axis is the distance between the mask stick 10b and the light-emitting element 150, and the Y-axis is the rate of increase of the width of the shadow area S. In the present embodiment, the width w of the shadow area S was measured by increasing the distance between the mask stick 10b and the light-emitting element 150 from 0.1 mm to 0.5 mm.

Referring to FIG. 7, it may be seen that the shadow area S increases as the mask stick 10b is disposed at a position farther away from the light-emitting element 150. Specifically, it may be seen that when the distance between the mask stick 10b and the light-emitting element 150 is a maximum value of 0.5 mm, the shadow area S increases by about 230% compared to when the distance between the mask stick 10b and the light-emitting element 150 is a minimum value of 0.1 mm.

Since the shadow area S decreases as the distance between the mask stick 10b and the light-emitting element 150 decreases as described above, the distance between the mask stick 10b and the light-emitting element 150 may be maintained at the minimum to realize a narrow bezel. In this case, when the distance between the mask stick 10b and the light-emitting element 150 is zero, the width w of the shadow area S may be the smallest. However, in this case, the mask stick 10b and the light-emitting element 150 may contact each other, thereby causing a tearing problem of the light-emitting element 150. Therefore, the shadow area S may be minimized when the distance between the mask stick 10b and the light-emitting element 150 is maintained at about 0.5 mm to 0.1 mm.

In addition, since the display device 200 of FIG. 5 is configured such that the support member 280 is prepared separately and then disposed over the base substrate 110, it is difficult to reduce the distance h between the base substrate 110 and the mask stick 10b. In other words, since it is difficult to precisely control the distance between respective layers having a micrometer size, when the height of the support member 280 is set to be larger even by a small value, the distance h between the light-emitting element 150 and the mask stick 10b may be increased to increase the shadow area S. On the other hand, when the height of the support member 280 is set to be smaller even by a small value, the mask stick 10b may come into contact with the cathode 152, thereby causing a tearing problem of the cathode 152.

For this reason, in the comparative example, a free space of about 0.3 mm or more is provided between the mask stick 10b and the cathode 152. Therefore, in the comparative example, the position of the mask stick 10b is moved upward compared to the present embodiment, so that the width of the passivation layer 170 disposed in the non-active area NA increases. For example, the width of the passivation layer 170 provided in the non-active area NA in the comparative example may be about 2.63 mm, while the width of the passivation layer 170 formed in the non-active area NA in the present embodiment may be about 1.915 mm.

In other words, when the support member 180 is disposed at a height of about 0.1 mm from the light-emitting element 150 disposed in the non-active area NA as in the present embodiment, the width of the passivation layer 170 for the shadow area S may be set to 2.0 mm or less to realize a narrow bezel. In this case, the overall width of the non-active area NA including the shadow area S may have a size of 3.3 mm or less.

FIG. 8 is a cross-sectional view illustrating a display device according to another embodiment of the present disclosure. In description of the present embodiment, features different from those of the foregoing embodiment will be mainly described.

Referring to FIG. 8, the display device 100 may further include a first encapsulation layer 191 and a second encapsulation layer 192.

The first encapsulation layer 191 may be located at the outermost of the members located in the non-active area NA and may cover the passivation layer 170 and the support member 180. For example, the first encapsulation layer 191 may be provided in the active area AA and the non-active area NA, and may cover the top and side portions of the passivation layer 170 and the support member 180 located under the first encapsulation layer 191. Accordingly, the light-emitting element 150 may be protected from external moisture, oxygen, or impact.

The first encapsulation layer 191 may be formed of an adhesive material and may further include a desiccant (or a moisture absorbent) to absorb moisture, oxygen, or the like from the exterior.

The second encapsulation layer 192 may be disposed on the top surface of the first encapsulation layer 191 to protect the light-emitting element 150 together with the first encapsulation layer 191. For example, the second encapsulation layer 192 may cover the upper front surface of the first encapsulation layer 191, and may be formed of a metal material.

A support member according to an embodiment of the present disclosure 180 may include a first layer 181, a second layer 182, and a third layer 183.

The first layer 181 may be disposed in the non-active area NA over the base substrate 110. For example, the first layer 181 may be spaced apart from the overcoat layer 130, and may be formed to contact an edge of the passivation layer 170. That is, the support member 180 may support the deposition mask 10 and also prevent the inorganic material from spreading outside the support member 180 when the inorganic material is deposited to form the passivation layer 170. Accordingly, the width S of the shadow area of the passivation layer 170 may be controlled to a desired size.

The first layer 181 may be formed of the same material as the overcoat layer 130. Since the first layer 181 is formed of the same material as the overcoat layer 130 as above, the overcoat layer 130 and the first layer 181 of the support member 180 may be formed using a single mask sheet. Accordingly, the first layer 181 and the overcoat layer 130 may be formed simultaneously without an additional mask sheet, thereby reducing processing time and cost.

The second layer 182 may be disposed on top of the first layer 181, and may be formed of the same material as the bank layer 140. Accordingly, a single mask sheet may be used to form the bank layer 140 and the second layer 182 over the overcoat layer 130 and the first layer 181, respectively.

The third layer 183 may be a control layer, and may be disposed over the second layer 182. As the control layer, the third layer 183 may control the overall thickness of the support member 180. For example, the height of the third layer 183 may be controlled to match the height of the light-emitting element 150.

The third layer 183 may be formed of the same material as the second layer 182. Since the third layer 183 is formed of the same material as the second layer 182, the second layer 182 and the third layer 183 may be formed by a single masking process when a halftone mask sheet or a slit mask sheet is used. Accordingly, the second layer 182 and the third layer 183 may be formed without an additional mask sheet, thereby reducing processing time and cost.

The first layer 181 may be formed to be higher than or equal to the height of the overcoat layer 130, the second layer 182 may be formed to be higher than or equal to the height of the bank layer 140, and the third layer 183 may be formed to be higher than or equal to the height of the light-emitting element 150. That is, the height of the support member 180 including the first layer 181, the second layer 182, and the third layer 183 may be formed to be equal to or greater than the total sum of the heights of the overcoat layer 130, the bank layer 140, and the light-emitting element 150.

When the height of the uppermost portion of the support member 180 is located than the height of the uppermost portion of the light-emitting element 150, the problem of tearing the cathode 152 after the deposition process may be caused. Accordingly, the support member 180 may be formed to have the same height as the light-emitting element 150 or to be higher than the light-emitting element 150 by a predetermined margin.

Specifically, the height of the support member 180 may be equal to the total sum of the heights of the overcoat layer 130, the bank layer 140, and the light-emitting element 150. However, if it is difficult to form the height of the support member 180 to be equal to the total sum of the heights of the overcoat layer 130, the bank layer 140, and the light-emitting element 150, the support member 180 may be formed so that the height thereof is higher than the total sum of the heights of the overcoat layer 130, the bank layer 140, and the light-emitting element 150 in order to solve the problem of tearing of the cathode 152. For example, the support member 180 may be arranged so that the height thereof has a margin of 0.1 mm to 0.2 mm above the total sum of the heights of the overcoat layer 130, the bank layer 140, and the light-emitting element 150.

According to an embodiment of the present disclosure, one or more trenches T may be provided over the capping layer 160, the light-emitting element 150, the bank layer 140, and the overcoat layer 130 disposed in the non-active area NA to be recessed towards the base substrate 110. In the present embodiment, two trenches T are shown, but one trench or three or more trenches may be formed.

The passivation layer 170 may be disposed within the trenches T. Accordingly, oxygen and moisture that would enter the side portions may be more effectively blocked by portions of the passivation layer 170 disposed within the trenches T.

According to an embodiment of the present disclosure, the non-active area NA of the base substrate 110 may include a first area NA1 disposed in the periphery of the base substrate 110 and removed by cutting and a second area NA2 disposed between the first area NA1 and the active area AA. That is, after the second encapsulation layer 192 is attached to the first encapsulation layer 191, a portion of the non-active area NA of the base substrate 110 may be cut by a cutting with penetrable scriber (CPS) process. The area that is cut and removed by the CPS process is the first area NA1, and the area that remains after the CPS process is the second area NA2.

The support member 180 may be disposed in the second area NA2 over the base substrate 110. Specifically, the support member 180 may be provided on a TFT disposed in the second area NA2 of the non-active area NA. Accordingly, the support member 180 may remain over the base substrate 110 after the CPS process.

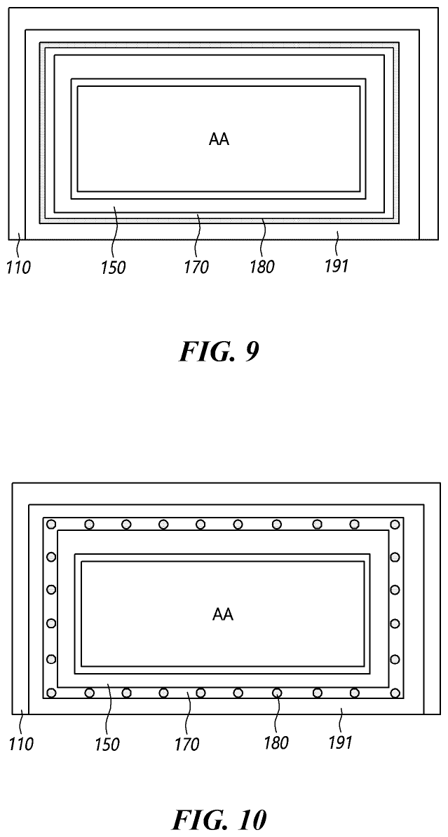

FIG. 9 is a plan view illustrating a display device according to an embodiment of the present disclosure.

Referring to FIG. 9, the support member 180 may be formed over the periphery of the base substrate 110 in the non-active area NA. For example, when the base substrate 110 is formed in the shape of a square plate, the support member 180 may be formed in the shape of a square column having a hollow interior. In this case, the support member 180 may be disposed in the second area NA2 over the base substrate 110, and the upper end thereof in contact with the deposition mask 10 may be formed to have a flat plate shape or a dome shape.

FIG. 10 is a plan view illustrating a display device according to according to another embodiment of the present disclosure. In description of the present embodiment, features different from those of the foregoing embodiments will be mainly described.

Referring to FIG. 10, a plurality of support members 180 may be provided and spaced apart from each other over the periphery of the base substrate 110 in the non-active area NA. For example, the support members 180 may be formed to have a prismatic shape, and the upper ends thereof in contact with the deposition mask 10 may be formed to have a flat plate shape or a dome shape.

The support members 180 are shown as formed in the shape of a square column in the present embodiment, but the support members 180 may be formed as triangular columns, pentagonal columns, or the like

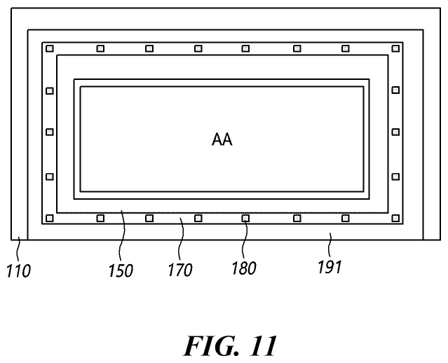

FIG. 11 is a plan view illustrating a display device according to according to another embodiment of the present disclosure. In description of the present embodiment, features different from those of the foregoing embodiments will be mainly described.

Referring to FIG. 11, a plurality of support members 180 may be provided and spaced apart from each other over the periphery of the base substrate 110 in the non-active area NA. For example, the support members 180 may be formed to have a circular column shape, and the upper ends thereof in contact with the deposition mask 10 may be formed to have a flat plate shape or a dome shape.

The above-described an embodiment of the present disclosure of the present disclosure are briefly reviewed as follows.

According to embodiments, provided is a display device including: a base substrate including an active area and a non-active area surrounding the active area; and a support member disposed in the non-active area over the base substrate, wherein the support member includes two or more layers.

According to embodiments, the support member may support a mask used in a deposition process for forming a film over the base substrate.

According to embodiments, the display device may further include: a subpixel portion disposed in the active area over the base substrate; an overcoat layer disposed in the non-active area over the base substrate; a bank layer disposed over the overcoat layer; a light-emitting element disposed over the subpixel portion and the bank layer; a capping layer disposed over the light-emitting element; and a passivation layer covering a top portion of the capping layer and side portions of the capping layer, the light-emitting elements, the bank layer, and the overcoat layer.

According to embodiments, the passivation layer may extend outward from the side portion of the overcoat layer to cover a portion of the base substrate.

According to embodiments, the support member may include a first layer disposed over the base substrate and a second layer disposed over the first layer, the first layer being formed of the same material as the overcoat layer, and the second layer being formed of the same material as the bank layer.

According to embodiments, the support member further may include a third layer disposed over the second layer, the third layer being formed of the same material as the second layer.

According to embodiments, the first layer may have a height higher than or equal to the height of the overcoat layer, the second layer may have a height higher than or equal to the height of the bank layer, and the third layer may have a height higher than or equal to the height of the light-emitting element.

According to embodiments, the display device may further include one or more trenches provided over the capping layer, the light-emitting element, the bank layer, and the overcoat layer disposed in the non-active area and recessed toward the base substrate.

According to embodiments, the passivation layer may be disposed in the trenches.

According to embodiments, the passivation layer may include a shadow area disposed in the non-active area, the shadow area having a width of 1.9 mm to 2.0 mm.

According to embodiments, the passivation layer may extend from the active area to the non-active area such that an extended edge thereof does not extend beyond the support member.

According to embodiments, the display device may further include: a first encapsulation layer covering the passivation layer and the support member; and a second encapsulation layer disposed on a top surface of the first encapsulation layer.

According to embodiments, the support member may be disposed between the passivation layer and the first encapsulation layer.

According to embodiments, the non-active area of the base substrate may include a first area provided in a peripheral portion of the base substrate to be cut and removed and a second area disposed between the first area and the active area, and the support member may be disposed in the second area.

According to embodiments, the support member may have a height of 0.003 mm to 0.005 mm.

According to embodiments, the support member may be provided over a peripheral portion of the base substrate in the non-active area.

According to embodiments, the support member may include a plurality of support members provided and spaced apart from each other over the peripheral portion of the base substrate in the non-active area.

According to embodiments, the support member may have a circular column shape or prismatic shape.

According to embodiments, an upper end of the support member may have a flat plate shape or a dome shape.

According to embodiments, the support member may be provided over a thin-film transistor disposed in the non-active area.

The above description has been presented to enable any person skilled in the art to make and use the technical idea of the present disclosure, and has been provided in the context of a particular application and its requirements. Various modifications, additions and substitutions to the described an embodiment of the present disclosure will be readily apparent to those skilled in the art, and the general principles defined herein may be applied to other an embodiment of the present disclosure and applications without departing from the spirit and scope of the present disclosure. The above description and the accompanying drawings provide an example of the technical idea of the present disclosure for illustrative purposes only. That is, the disclosed an embodiment of the present disclosure are intended to illustrate the scope of the technical idea of the present disclosure.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a base substrate including an active area and a non-active area surrounding the active area; and
a support member disposed in the non-active area of the base substrate,
wherein the support member includes two or more layers.

2. The display device of claim 1, wherein the support member is configured to support a mask for a deposition process for forming a film on the base substrate.

3. The display device of claim 1, further comprising:
a subpixel disposed in the active area of the base substrate;
an overcoat layer disposed in the non-active area of the base substrate;
a bank layer disposed on the overcoat layer;
a light-emitting element disposed on the subpixel and the bank layer;
a capping layer disposed on the light-emitting element; and
a passivation layer covering a top surface of the capping layer and side surfaces of the capping layer, the light-emitting element, the bank layer, and the overcoat layer.

4. The display device of claim 3, wherein the passivation layer extends outward from the side surface of the overcoat layer to cover a portion of the base substrate.

5. The display device of claim 3, wherein the support member includes a first layer disposed on the base substrate and a second layer disposed on the first layer,
wherein the first layer is a same material as the overcoat layer, and the second layer is a same material as the bank layer.

6. The display device of claim 5, wherein the support member further includes a third layer disposed on the second layer, wherein the third layer being is a same material as the second layer.

7. The display device of claim 6, wherein the first layer has a height greater than or equal to a height of the overcoat layer,
wherein the second layer has a height higher than or equal to a height of the bank layer, and
wherein the third layer has a height higher than or equal to a height of the light-emitting element.

8. The display device of claim 3, further comprising:
one or more trenches provided in the capping layer, the light-emitting element, the bank layer, and the overcoat layer, wherein the one or more trenches are disposed in the non-active area and are recessed toward the base substrate.

9. The display device of claim 8, wherein the passivation layer is disposed in the one or more trenches.

10. The display device of claim 3, wherein the passivation layer includes a shadow area disposed in the non-active area, the shadow area having a width of 1.9 mm to 2.0 mm.

11. The display device of claim 3, wherein the passivation layer extends from the active area to the non-active area, and
wherein an outer edge of the passivation layer terminates at the support member.

12. The display device of claim 3, further comprising:
a first encapsulation layer covering the passivation layer and the support member; and
a second encapsulation layer disposed on a top surface of the first encapsulation layer.

13. The display device of claim 12, wherein the support member is disposed between the passivation layer and the first encapsulation layer.

14. A display device, comprising:
a base substrate including an active area and a non-active area surrounding the active area;
a support member disposed on the base substrate in the non-active area, wherein the support member includes two or more layers; and
a passivation layer on the base substrate,
wherein the support member is disposed at an end face of the passivation layer.

15. The display device of claim 14, wherein the support member has a height of 0.003 mm to 0.005 mm.

16. The display device of claim 14, wherein the support member is disposed in a peripheral portion of the base substrate in the non-active area.

17. The display device of claim 14, wherein the support member is one of a plurality of support members disposed in the peripheral portion of the base substrate in the non-active area, the plurality of support members spaced from each other.

18. The display device of claim 17, wherein the support member has a circular column shape or prismatic shape.

19. The display device of claim 14, wherein an upper end of the support member has a flat plate shape or a dome shape.

20. The display device of claim 1, wherein the support member is overlaps a thin-film transistor disposed in the non-active area.
